(19) United States
(12) Patent Application Publication
(10) Pub. No.: US 2005/0082089 A1
(43) Pub. Date: Apr. 21, 2005

(54) Stacked interconnect structure between copper lines of a semiconductor circuit

(76) Inventors: Stephan Grunow, Dallas, TX (US); Satyavolu Srinivas Papa Rao, Garland, TX (US); Noel M. Russell, Plano, TX (US)

Correspondence Address: TEXAS INSTRUMENTS INCORPORATED, P O BOX 655474, M/S 3999, DALLAS, TX, 75265, US

(21) Appl. No.: 10/688,452

(22) Filed: Oct. 18, 2003

(51) Int. Cl. H05K 3/20; H05K 1/11

(52) U.S. Cl. 174/266; 29/852; 29/831; 174/257

(57) ABSTRACT

A stacked interconnect structure to connect a first layer copper line with a second layer copper line and method of making the same includes depositing a barrier layer over the inner surfaces of a via extending through a first dielectric layer between the first and second layer copper lines. The first barrier layer provides a barrier to copper diffusion into the dielectric layer. The first barrier layer is then selectively etched from the bottom surface of the via, after which a second barrier layer is deposited over the vertical and bottom surfaces of the via. The second barrier layer also provides a barrier to the diffusion of copper, but is less resistive than the first barrier, and ensure wettability of the copper.

### BACKGROUND

Copper has become increasingly the metal of choice used to form interconnects in the manufacture of integrated circuits. Copper provides the benefit of low resistivity, which allows for greater circuit operating frequencies. Copper also has the additional benefit of reduced susceptibility to electromigration failure as compared to the more traditional aluminum or aluminum alloy metal interconnects.

Low dielectric constant (low-k) and ultra low dielectric constant (ULK) materials are now being used to form the layers above the surface of the semiconductor in which multiple layers of copper interconnect are formed. Copper has a tendency to diffuse into these more porous dielectric layers leading to circuit reliability issues. Barrier layers are typically used to encapsulate the copper metal interconnect lines as they are formed in the dielectric layers to prevent Cu diffusion.

The use of these barriers can become problematic when interconnecting copper lines between different interconnect layers of a semiconductor circuit during the manufacturing process. When connecting the copper line from a first interconnect layer to a copper line being formed in a second interconnect layer, a vertical (or stacked) interconnect structure is typically formed over a portion of the first copper line. The stacked structure typically includes a via, which starts out as an empty vertical shaft extending down through the dielectric that separates and electrically isolates the first layer of interconnect from the second. Additional copper is deposited into and ultimately fills the via. A portion of the second layer copper line is formed over and in physical contact with the copper deposited in the via to provide a conductive path between the copper lines of the two different metallization layers through the via.

To prevent migration of copper through the sidewalls of the via (typically defined by the dielectric layer) as well as through the trenches in the dielectric used to form the copper lines, a barrier layer is typically first deposited on the inside walls of the via prior to the introduction of copper to form a barrier to diffusion of the copper. One commonly used technique is to first use a pre-barrier sputter etch (PSE) with Ar+ used as the sputtering species. This process step is primarily designed to clean the bottom of the via of residues remaining from previous process steps. The via should be substantially aligned over the first layer copper line, so that its bottom surface will be the copper surface of the copper line. Cleaning residues from the bottom of the via (essentially the surface of the first level copper line), decreases the resistance of the contact between the two copper lines ultimately formed through the via.

A barrier layer is then deposited on the inner walls of the via (including the bottom surface, as well as the sidewalls of the trench defining the second layer copper line. Finally, copper or copper alloy is deposited and filled into the via and the second layer copper or copper-alloy line is formed in its trench over the top of the via.

There are some significant problems with this approach to building stacked interconnect structures between copper lines on different interconnect levels. First, the PSE step causes some re-sputtering of copper from the first layer copper line, and some of this copper is deposited directly onto the vertical walls of the via and, thus, is in direct contact with the dielectric. Copper migration from the re-sputtered copper can occur notwithstanding the barrier layer that is then deposited to prevent such migration from the copper filling the via. This causes significant impact on circuit reliability. Secondly, the PSE step causes flaring of the via walls at the top of the via or flaring of the metal line (trench) walls at the top of the metal line, which erodes the separation between the copper lines on the second level of interconnect at the vias.

With respect to the barrier layer, the thicker the barrier layer is the greater the barrier's efficacy in preventing diffusion of additional copper into the dielectric from the copper filling the via and from the second level copper line. However, the thicker the barrier layers are the more resistive are the conductive portions of the vias. This can cause the circuit to fail to operate at the frequencies for which it is intended. The use of a substantially thick barrier layer to prevent Cu diffusion results in the deposition of a significant amount of barrier material at the bottom of the via where it contacts the first layer copper line. The barrier layer at the bottom of the via contributes significantly to the via resistance, particularly when using advanced barrier materials that typically exhibit high resistivity.

### SUMMARY

This disclosure describes methods and apparatus that address one or more of the issues noted above. In at least some embodiments, a via is formed between first and second layer copper lines by depositing a first barrier layer over the inner wall and bottom surfaces of the via, then selectively removing the first barrier layer from the bottom surface of the via, and then depositing a second layer made of material that also forms a barrier to copper migration, ensures adequate wettability of copper and may improve wettability relative to the first barrier layer, and may be relatively less resistive than the first barrier layer. In at least some embodiments, the selective removal of the barrier layer from the bottom of the via may be performed in the same processing chamber as the deposition of the second layer.

### BRIEF DESCRIPTION OF THE DRAWINGS

For a detailed description of the preferred embodiments of the invention, reference will now be made to the accompanying drawings in which:

FIG. 1A is a cross-sectional view of a portion of a semiconductor circuit that shows a stacked interconnect structure manufactured in accordance with the prior art;

FIG. 1B is a cross-sectional view of a portion of a semiconductor circuit that shows a first pre-barrier sputter etch (PSE) step in the process of building a stacked interconnect structure in accordance with the prior art;

FIG. 1C is a cross-sectional view of a portion of a semiconductor circuit that shows results of the pre-barrier sputter etch (PSE) step and a second barrier deposition step in the process of building a stacked interconnect structure in accordance with the prior art;

FIG. 1D is a cross-sectional view of a portion of a semiconductor circuit that shows results of a third step in the process of building a stacked interconnect structure in accordance with the prior art;

FIG. 2A is a cross-sectional view of a portion of a semiconductor circuit that shows the results of a direct barrier deposition processing step performed on a stacked interconnect structure in accordance with at least one embodiment of the invention;

FIG. 2B is a cross-sectional view of a portion of a semiconductor circuit that shows the results of a selective etch processing step performed on a stacked interconnect structure in accordance with at least one embodiment of the invention;

FIG. 2C is a cross-sectional view of a portion of a semiconductor circuit that illustrates the undesirable results of a copper deposition and fill processing step performed on a misaligned stacked interconnect structure absent the processing step of 2D.

FIG. 2D is a cross-sectional view of a portion of a semiconductor circuit that shows the results of a flash barrier deposition processing step performed on a stacked interconnect structure in accordance with at least one embodiment of the invention;

FIG. 2E is a cross-sectional view of a portion of a semiconductor circuit that shows the results of a copper deposition and fill processing step performed on a stacked interconnect structure in accordance with at least one embodiment of the invention;

### NOTATION AND NOMENCLATURE

Certain terms are used throughout the following description and in the claims to refer to particular process steps, process materials and structures resulting therefrom. As one skilled in the art will appreciate, those skilled in the art may refer to a process, material or resulting structure by different names. This document does not intend to distinguish between components, materials or processes that differ in name but not function. In the following discussion and in the claims, the terms “including” and “comprising” are used in an open-ended fashion, and thus should be interpreted to mean “including, but not limited to . . . .”

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims, unless otherwise specified. In addition, one skilled in the art will understand that the following description has broad application, and the discussion of any embodiment is meant only to be exemplary of that embodiment, and not intended to intimate that the scope of the disclosure, including the claims, is limited to that embodiment.

Moreover, those of skill in the art will recognize that there may be alternative processing materials or steps that provide the claimed characteristics disclosed herein, and that some materials may be more optimal than others. While this disclosure attempts to list such alternatives, under no circumstances should any such list be deemed exhaustive. Finally, parametric information has been disclosed for some of the processing steps disclosed herein to aid one of ordinary skill to practice the invention. Wherever possible, such parametric data is provided in typical ranges, but in no way should the specification of any such range be construed as an attempt to limit the range in which various embodiments of the invention are intended to operate unless explicitly stated otherwise.

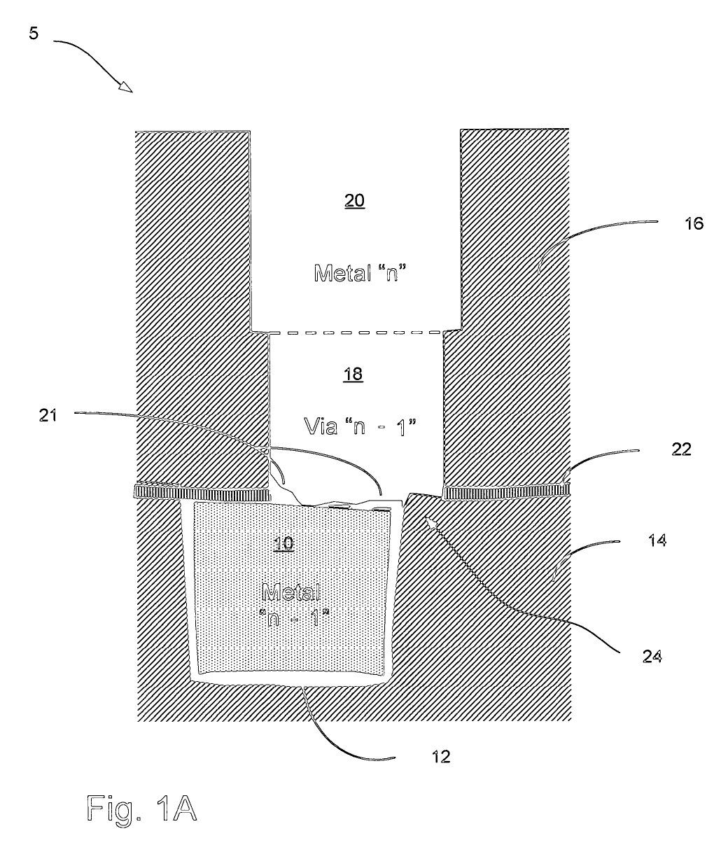

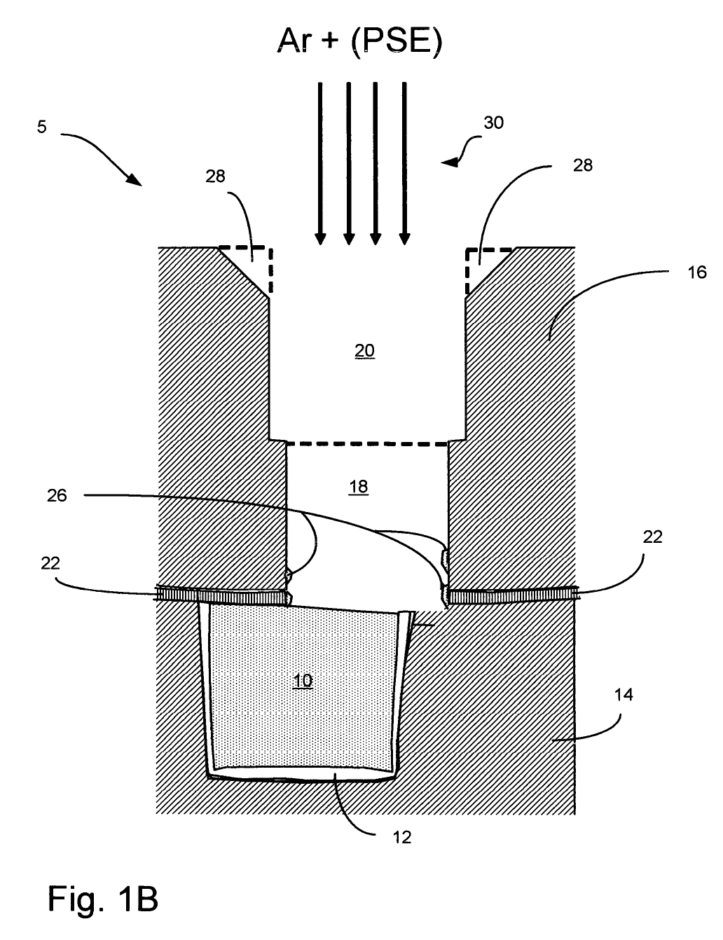

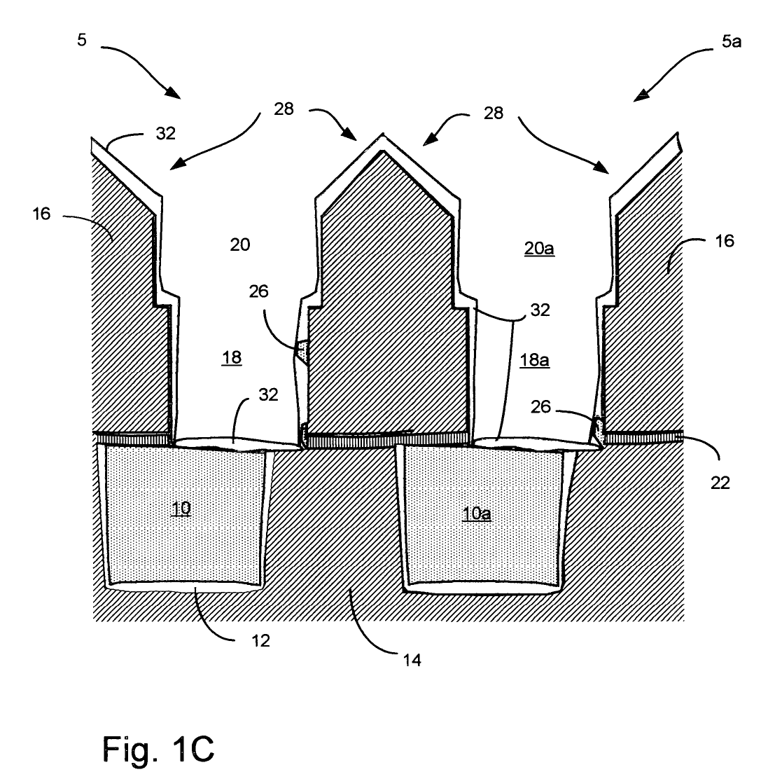

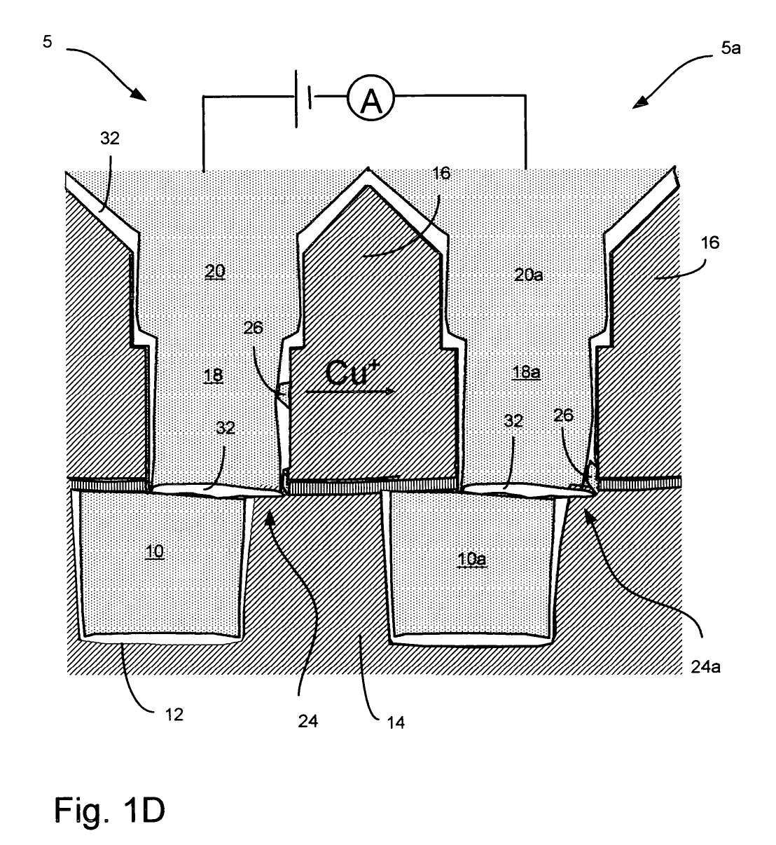

Referring now to FIG. 1A, a cross-sectional view of a commonly employed stacked interconnect structure 5 is shown. By a number of processing steps known in the art, a first layer (Metal “n−1”) copper line 10 is isolated from other first layer copper lines (“not shown”) and other proximate components (e.g. transistors, resistors, capacitors, etc.) by dielectric layer 14. A second dielectric layer 16 is then deposited to isolate copper line 10 from a second layer (Metal “n”) of copper lines to be formed in later processing steps. As previously mentioned, the dielectric layers 14, 16 used in semiconductor circuits today are often characterized by low or ultra-low dielectric values of the dielectric constant k. This typically renders such dielectric layers more porous and susceptible to copper migration, which decreases reliability of the circuit over time. Thus, it is known in the art to provide a barrier layer 12 that is resistant to copper migration and thus serves to isolate the copper from the dielectric.

In an embodiment of the instant invention the dielectric layer 14, 16 is formed comprising silicon oxide. In a further embodiment of the instant invention low and/or ultra low-k dielectric material, such as siloxane, silsesquioxane (SSQ)-based materials, e.g., MSQ (methylsilsesquioxane) or hydrogensilsesquioxane (HSQ), silica-based materials, e.g., carbon- or fluorine-doped silica glasses, organic-polymer-based materials, amorphous-carbon-based materials, and any other dielectric material that exhibits low or ultra low-k characteristics, can be used to form the dielectric layers 14, 16. For purposes of this invention a low-k dielectric can be considered to be material possessing a dielectric constant of less than 3.9, which is the dielectric constant of silicon dioxide. A dielectric can be considered to be an ultra low-k dielectric material if it possesses a dielectric constant of less than 2.6.

As illustrated in FIG. 1A, a via 18 has been opened that is preferably aligned substantially with a portion of the first layer copper line 10. In the example of FIG. 1A, there is illustrated a misalignment 24 between the via and the first layer copper line 10. Such a misalignment can occur as a function of the layout of the via and metal lines, and limitations on the ability of semiconductor photolithographic equipment to align the masks used to define the via 18 and the trench 20 with the already created first layer copper line 10.

As indicated in the figure, a slightly wider trench 20 was opened in the dielectric layer 16 for a second layer copper line that is to be electrically coupled to the first layer copper line 10 through via 18. The trench 20 is preferably aligned with via 18. An etch-stop layer 22 was previously deposited, and provides a barrier such that the etching process used to open the via 18 in dielectric layer 16 does not continue substantially past the top surface of the first layer copper line 10. The foregoing steps may be performed using standard processing techniques known to those of skill in the art. Such techniques include forming a patterned photoresist layer on the dielectric layer 16, followed by anisotropic etching of the exposed regions of the dielectric layer 16. The via 18 and trench 20 can be of a single width as shown in FIG. 1A or they can comprise multiple widths without departing from the scope of the instant invention. Residues 21, including oxidized copper, remain on the bottom wall of the via 18 formed by first layer copper line 10, as a result of the various photolithographic and processing steps required to define and etch the via opening 18.

With reference to FIG. 11B, a pre-barrier sputter etch (PSE) processing step known to those of skill in the art is applied to the stacked interconnect structure 5. Argon (Ar+) is typically used as a sputtering species to clean the residues 21 from the bottom surface of via 18. Copper from the first layer copper line 10 is re-sputtered 26 during this process, and some of it adheres to the side walls of via 18 and/or trench 20. The PSE process also causes flaring 28 of the walls of the dielectric 16 at the top of the trench 20 for defining the second level copper line.

FIG. 1C illustrates a cross-section of two (5, 5a) of the stacked interconnect structures in proximity to one another. FIG. 1C illustrates a known barrier deposition process that deposits barrier layers 32 over the exposed surface of the semiconductor and particularly the sidewalls and bottom surfaces of vias 18, 18a and trenches 20, 20a. Re-sputtered copper 26 resulting from the PSE is now trapped on the surface of the dielectric 16 and beneath the just deposited barrier layer 32. The barrier layer 32 is typically the same material as is used to form barrier layer 12 for the first layer of metal. As previously discussed, the barrier layer 32 is intended to prevent migration of copper into the dielectric layer 16 from the copper that will fill eventually fill the via 18 and the trench 20. Notwithstanding, the re-sputtered copper 26 is free to migrate into the dielectric layer 16. As previously mentioned, this can lead to reliability issues for semiconductors suffering from this defect.

FIG. 1D illustrates the pair of stacked interconnect structures 5, 5a after a known process of filling the vias 18, 18a and the trenches 20, 20a with copper, which typically includes three sub-steps of a copper seed deposition, electrochemical deposition ECD copper fill, and a metal polishing step. It can be seen that the extent of the second layer metal lines 20, 20a are now more proximate than originally desired and this can lead to leakage and even short circuits between the lines. To circumvent this problem, initial layout rules will have to dictate that the copper lines be separated by a greater distance to begin with to compensate for the flaring. This in turn will cause the layout to occupy more real estate and thus make the circuit more expensive to manufacture. It should also be noted that even though the vias 18, 18a are misaligned with copper lines 10, 10a, the copper in vias 18, 18a is prevented from migrating into dielectric layer 14 through the misaligned area 24, 24a by the barrier layer 32.

There are numerous materials of which the barrier 32 may be formed and a number of process techniques by which the deposit of the barrier layer may be accomplished. Generally speaking, the thicker the layer, the better the copper barrier qualities of the barrier layer. However, as the barrier layer 32 is thickened to improve its properties for reducing copper migration into the dielectric layers 16 (and layer 14 in the case of misalignment), the resistance of the contact goes up and the maximum frequency of operation of the circuit goes down. If the barrier layer 32 is thinned to lower resistance, this will open the possibility to insufficient diffusion-barrier properties, pin-holes and dielectric voiding.

One problem is that as some materials using some techniques are deposited, the rate of deposition of the material may be, for example, twice as great for the horizontal bottom surface of the via then for its vertical side walls. This is problematic because the current flow will be through the bottom of the via and thus significant resistance may encountered through this thick barrier layer. One possible solution to the disparate rate of growth between the surfaces would be to use conformal ultra-thin barrier materials and processing techniques instead. In the case of conformal layers, the rate of deposit of material (and thus the thickness of the barrier layer) is virtually the same on both the vertical and horizontal surfaces of the vias 18, 18a. These materials tend to provide strong diffusion barriers to copper even though relatively thin, but their resistivity can overwhelm any improvement in their thickness.

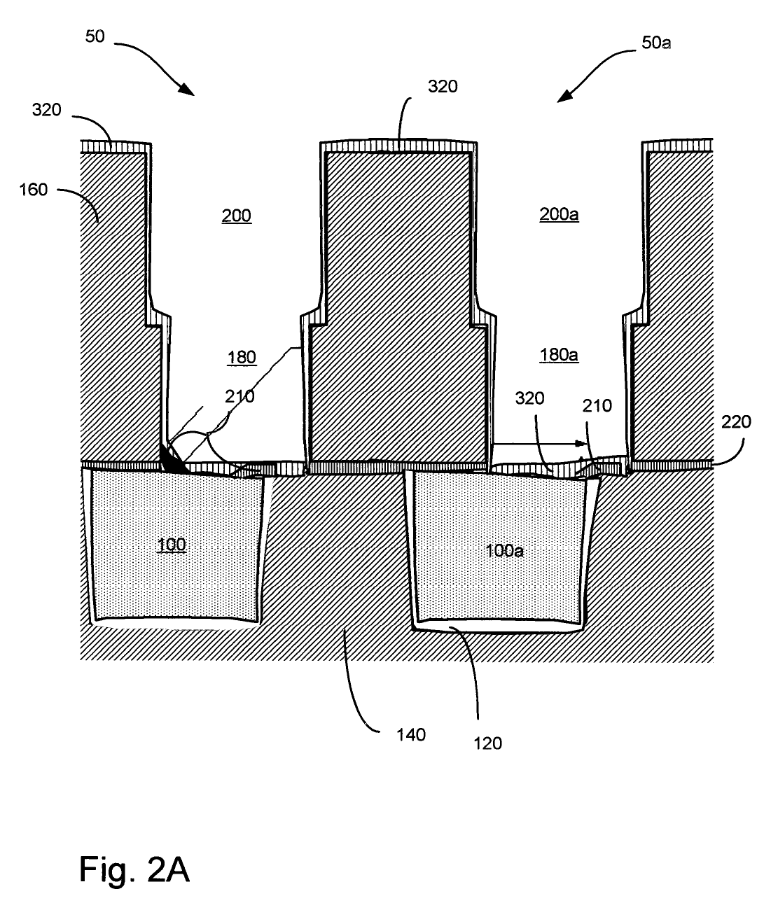

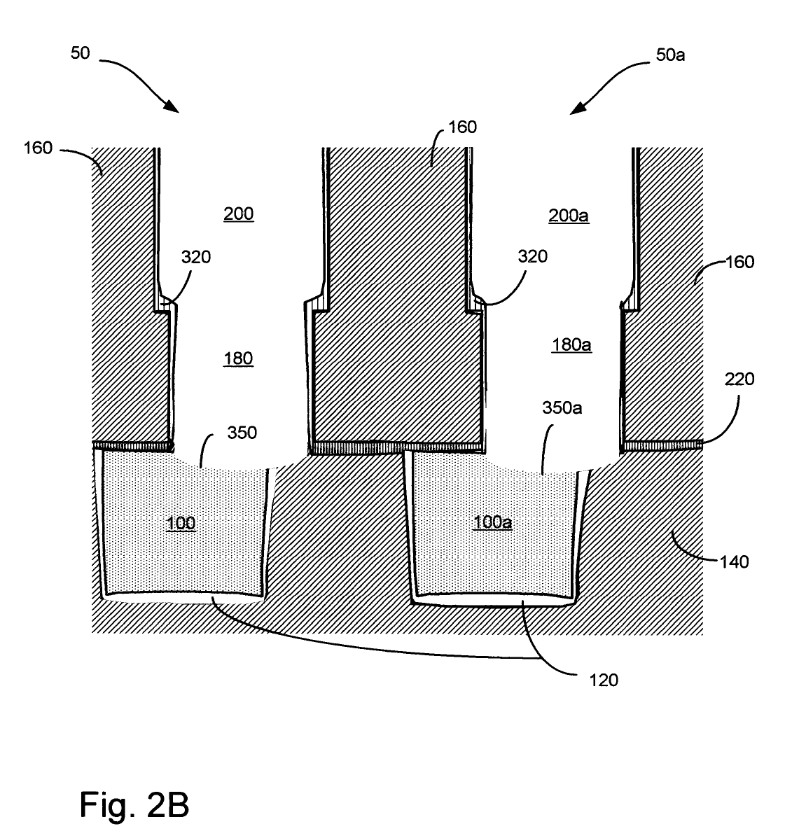

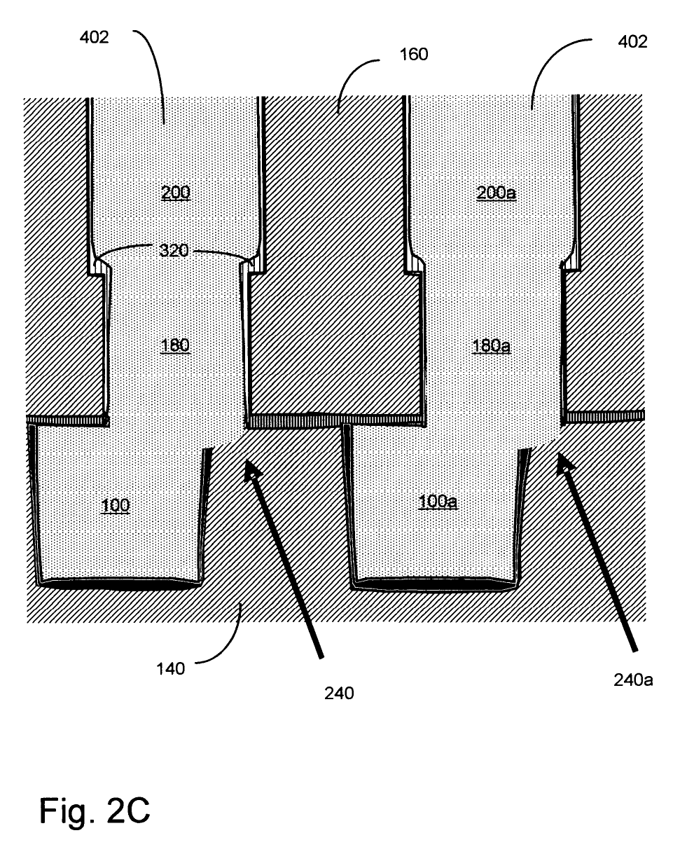

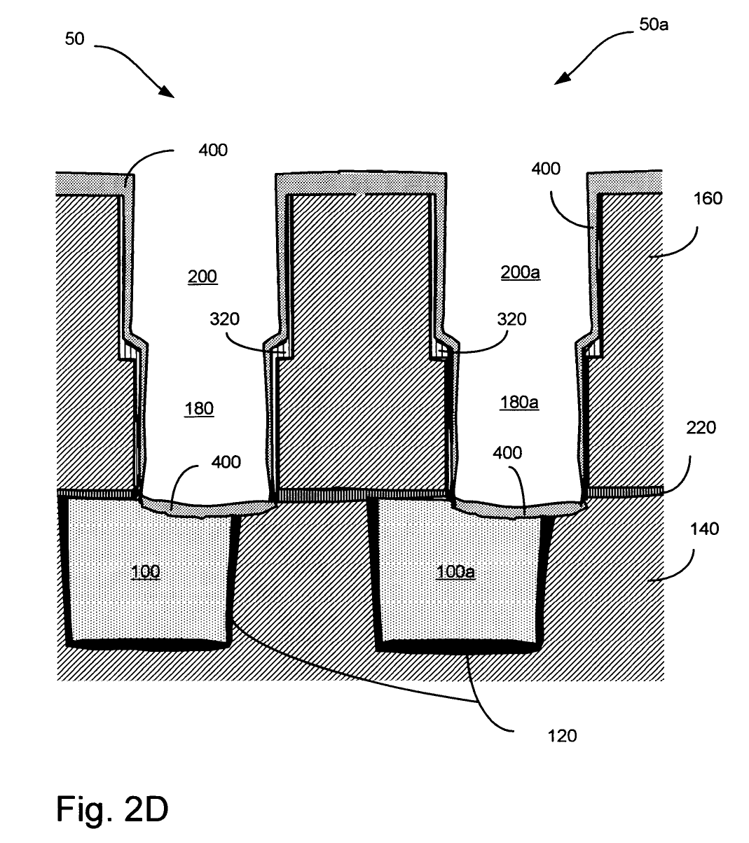

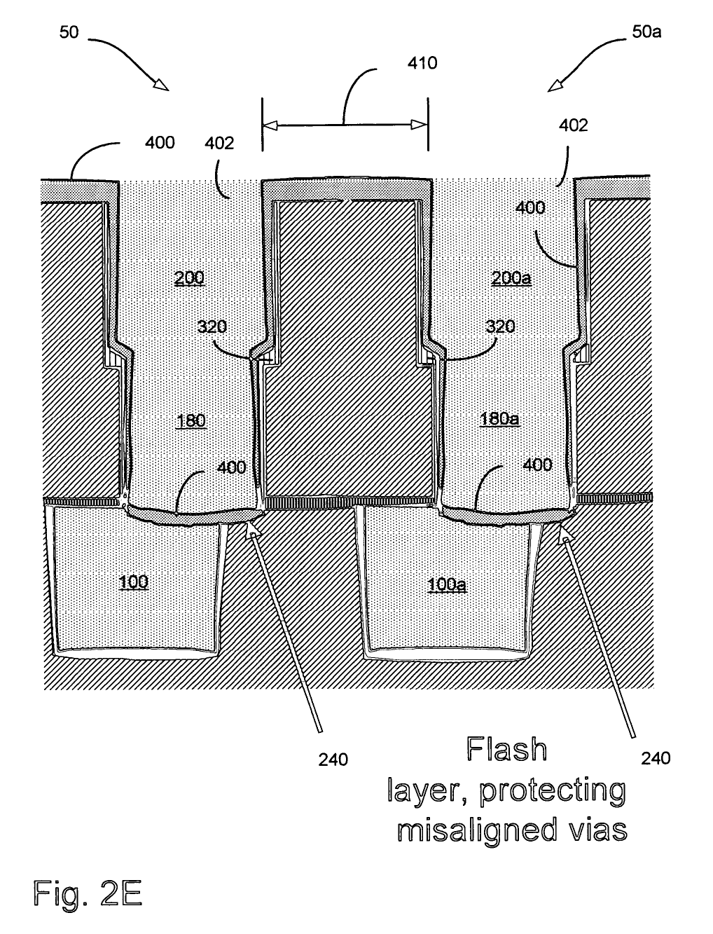

With reference to FIG. 2A, a cross-section of a pair of stacked interconnect structures 50, 50a is illustrated, wherein the structures are subjected to a processing step that skips the PSE step of the prior art (as previously discussed above) and directly deposits a barrier layer 320 over the side walls of the vias 180, 180a and the trenches 200, 200a, as well as directly over the residues 210 on the bottom of the vias 180, 180a. Prior to the barrier deposition processing illustrated in FIG. 2A, the stacked structures 50, 50a were constructed using the same known and conventional processing steps as those used to construct stacked structures 5, 5a of FIG. 1A.

As will be explained in further detail below, the present invention has rendered the concern for the type of material used to form the barrier layer 320 much less significant than it is when using the prior art method described above. Those of skill in the art will recognize that while conformal barrier layers may be preferred for barrier layer 320 because of their thin nature and strong copper barrier characteristics, barrier materials other than conformal barrier layers may provide more or less optimal barriers to copper may and may also be substituted therefore without exceeding the intended scope of the invention. Any of the following materials may be used to form the first barrier, including but not limited to TINSi, Ta, TaN, TaSiN, Ti, TiN, W, WN, WSIN, WCN, and Ru.

The barrier layer 320 deposited by the deposition process of FIG. 2A can be a thin (typically between 10-500 Angstroms and preferably between 20 and 300 Angstroms), relatively high-resistive conformal layer of a material such as plasma+silane-treated chemical vapor deposition (CVD) of titanium silicon nitride (TiNSi). In the alternative, an atomic layer deposition (ALD) created layer such as ALD tantalum nitride (TaN) may be used. Also, ionized physical vapor deposition (PVD) created non-conformal layers such as tantalum (Ta) and/or tantalum nitride (TaN) may also be used to form the barrier layer in this step of the process of the invention. Each of these materials and techniques are known to those of skill in the art.

In a first embodiment, a CVD process may be used to form a TiNSi layer as the conformal diffusion-barrier layer 320 as illustrated in FIG. 2A. The deposition process comprises first forming a titanium nitride (TiN) using metal-organic chemical vapor deposition (MOCVD). Preferably the MOCVD process comprises the thermal decomposition of TDMAT, [(CH₃)₂N]₄Ti. TDMAT is a liquid and is preferably introduced into the reactor using a carrier gas, such as He or N₂. The decomposition is preferably achieved within a temperature range of 300° C. to 500° C. and at a pressure between 0.1 to 50 Torr. In an alternate embodiment, C₂H₅ can be used in place of CH₃ so that the precursor would be [(C₂H₅)₂N]₄Ti.

In another embodiment, the precursor could be [(CH₃)(C₂H₅)N]₄Ti. Following the formation of the initial TiN layer, the material is exposed to plasma of approximately 1.5 to 3 W/cm2 plasma density, preferably using a mixture of hydrogen and nitrogen, to densify the TiN layer and to replace carbon species with nitrogen species in the carbon-containing TiN layer. The aforementioned steps of initial TIN deposition followed by plasma treatment can be repeated multiple times to form multi-layered plasma-treated TiN layers. In one embodiment of the instant invention, two plasma-treated TIN layers are formed with thicknesses of between 20-40 angstroms each. Following the final plasma treatment, a heating step is performed in a silane, disilane, or any other ambient that can produce silicon in the film. This step is performed at approximately 350° C. to 500° C. at 0.1 to 50 torr for approximately 5 to 240 seconds. This results in the formation of the TiNSi layer as conformal barrier layer 320.

Discontinuities in the barrier layer can result in reactions between the porous low-k dielectric 140, 160 and the copper-electrolyte solution during subsequent electro-chemical deposition (ECD) of copper. The use of a thin and conformal barrier such as CVD TiNSi is effective in eliminating this dielectric-voiding mechanism. Those of skill in the art will recognize, however, that other materials or processes providing more or less optimal results may be substituted therefore without exceeding the intended scope of the present invention.

In FIG. 2B, the high-resistivity barrier layer 320 is selectively etched from the bottoms 350, 350a of the vias 180, 180a. This can be accomplished, for example, by tuning process conditions in a PVD barrier chamber to achieve a net-etch at the bottom of the vias 180, 180a. If a Ta deposition chamber is used to process this step, the conditions can be tuned as follows: I) the target DC power is reduced relative to the barrier deposition, for example in the range of 0-1500 Watts; 2) an AC wafer bias of between 300 to 2000 Watts can be applied; 3) an RF excitation coil power of between 400-2000 W with an optional DC bias power of between 0-500 W; and 4) establishing a chamber pressure of 1-50 mTorr. The etch may be in the range of 10-2,000 Angstroms and is preferably to a depth that ensures the etch level clears the bottom of the vias. The range will typically range between 20 and 1000 Angstroms.

This etching step performs two important functions. First, it removes the barrier layer from its bottom surface to substantially eliminate the resistance seen by current flowing through the vias 180, 180a between the first and second layer copper lines. Secondly, it removes the residue that was otherwise removed typically by the PSE step, but without the undesirable side-effects created by the PSE as was previously described (i.e. copper re-sputtering and flaring of the dielectric walls). However, this etching step does expose dielectric to the inside of the vias 180, 180a if there is misalignment of the vias with the first layer copper line 100, 100a.

FIG. 2C illustrates the undesirable results of going straight to Cu-seed and/or electrochemical deposition of the copper 402 to fill the vias 180, 180a and the trenches 200, 200a immediately following the etching process previously discussed. It can be seen from FIG. 2C that any misalignment 240, 240a of the vias 180, 180a with the first layer copper lines 100, 100a will provide an opportunity for copper diffusion from the vias 180, 180a into the dielectric layer 140. Without additional processing, the design rules for the circuit would have to be relaxed to overcome variations in the alignment tolerances of the photolithographic processing equipment. This would lead to increased manufacturing costs of the circuit.

Therefore, as illustrated in FIG. 2D, a second barrier deposition is performed that forms a barrier layer 400 over the walls of the vias 180, 180a including the bottom surface 400. This barrier is designed to have the characteristics necessary to protect against copper diffusion into dielectric 140 through misalignment 240, while exhibiting relatively low resistivity and increasing/providing sufficient wettability to copper. In one embodiment, the layer can be formed of tantalum using a flash deposition process in the same chamber as used to perform the selective etch to remove the diffusion barrier layer 320 (and the residues 210) from the bottom of the vias 180, 180a as illustrated in FIG. 2B. The conditions for the deposition can be the same as those used for deposition of the diffusion barrier layer 320 if a PVD Ta layer is used for the flash barrier 400. The flash layer 400 can range in thickness from 10-300 Angstroms with a typical range of 20-150 Angstroms. Other materials that may be used as the flash barrier layer 400 are TaN/Ta, Ru, or any other material that provides sufficient and/or increased wettability of copper, exhibits relatively low resistivity and provides a diffusion barrier against copper.

Finally, FIG. 2E illustrates the state o This disclosure describes methods and apparatus that address one or more of the issues noted above. In at least some embodiments, a via is formed between first and second layer copper lines by depositing a first barrier layer over the inner wall and bottom surfaces of the via, then selectively removing the first barrier layer from the bottom surface of the via, and then depositing a second layer made of material that also forms a barrier to copper migration ensures sufficient wettability of copper and, is relatively less resistive than the first barrier layer. In at least some embodiments, the selective removal of the barrier layer from the bottom of the via may be performed in the same processing chamber as the deposition of the second layer.f the stacked structure 50, 50a after a Cu or Cu-alloy seed deposition and/or Cu ECD fill process that leads to the vias 180, 180a and trenches 200, 200a being filled with copper or copper alloy 402. As can be see, the flash barrier layer 400 on the bottoms of the vias 180, 180a provides a copper diffusion barrier to prevent migration through the misaligned areas 240, 240a. The flash barrier layer 400 further provides adequate if not improved wettability of the copper 402 to the barrier 400 of the vias 180, 180a and the trenches 200, 200a.

In summary, embodiments of the invention eliminate the need for the known PSE step in building stacked interconnect structures, which leads to the undesirable effects of flaring of the dielectric walls and re-sputtering of copper onto the walls of the structure prior to deposition of a diffusion barrier. Moreover, more flexibility is provided regarding the choices for materials and processes for forming the initial barrier layer. Thin conformal barrier layers with good diffusion barrier characteristics can be used despite their high resistivity because they are selectively etched from the bottom surfaces of the vias making contact with a first layer metal interconnect. Finally, any exposure to the dielectric layers through the selectively etched surface of the vias due to misalignment are sealed by way of a flash barrier deposition that not only acts as a diffusion barrier to migration of copper through the misaligned vias, but also provides sufficient and can improve wettability of the copper for adherence purposes and relatively low resistivity characteristics that facilitate good low-resistance contact between the first and second layer copper lines.

1. A method of forming an interconnect between a first layer copper line and a second layer copper line of a semiconductor circuit, said method comprising:
forming a via through a first dielectric layer to expose the surface of the first layer copper line;
depositing a first barrier layer over inner sidewall and bottom surfaces of the via, the barrier layer providing a diffusion barrier against copper;
etching selectively the bottom surface of the via to substantially eliminate the barrier layer from the bottom surface; and
depositing a second barrier layer over the inner surfaces of the via, the second barrier layer providing a diffusion barrier against copper and ensures sufficient wettability of copper.

2. The method of claim 1 further comprising forming a trench in the dielectric layer, a portion of which lies substantially over the via; wherein the first and second barrier layers are deposited on inner surfaces of the trench.

3. The method of claim 1 further comprising the step of depositing copper in the inner surfaces of the via and trench, thereby substantially filling the via and trench with the deposited copper.

4. The method of claim 1 wherein the first barrier layer is a conformal barrier layer.

5. The method of claim 4 wherein the conformal barrier layer is a layer of plasma+silane treated CVD TiNSi.

6. The method of claim 4 wherein the conformal barrier layer is an ALD layer of TaN.

7. The method of claim 1 wherein the first barrier layer is an ionized PVD layer of at least one of the following materials: Ta, TaN.

8. The method of claim 1 wherein the first barrier layer comprises at least one of the following materials: TiNSi, Ta, TaN, TaSiN, Ti, TiN, W, WN, WSiN, WCN, and Ru.

9. The method of claim 1 wherein the selective etching is performed in a PVD barrier chamber.

10. The method of claim 1 wherein the second barrier layer is a flash PVD layer of Ta.

11. The method of claim 1 wherein the flash barrier layer is a PVD layer of Ta and wherein depositing the second barrier layer is performed in the same PVD barrier chamber as the selective etching.

12. The method of claim 1 wherein the second barrier layer has lower resistivity with respect to the first barrier layer.

13. A stacked interconnect structure for coupling a first layer copper line with a second layer copper line comprising:
a via extending through a first dielectric layer to expose the surface of the first layer copper line, the via having an inner core comprising copper;
a first barrier layer covering substantially vertical and bottom surfaces of the inner core; and
a second barrier layer substantially covering the vertical surfaces and not the bottom surface of the via, the second barrier layer lying between the first barrier layer and the first dielectric layer; and
wherein the second barrier layer provides a diffusion barrier against copper and the first barrier layer provides a barrier to copper, ensures wettability of the copper, and is relatively lower in resistivity than the second barrier layer.

14. The structure of claim 13 wherein a top surface of the via is coupled to a portion of the second layer copper line.

15. The structure of claim 13 wherein the second barrier layer is a conformal barrier layer.

16. The structure of claim 15 wherein the conformal barrier layer is a layer of plasma+silane treated CVD TiNSi.

17. The structure of claim 15 wherein the conformal barrier layer is an ALD layer of TaN.

18. The structure of claim 13 wherein the second barrier layer is an ionized PVD layer of at least one of the following materials: Ta, TaN.

19. The structure of claim 13 wherein the second barrier layer comprises at least one of the following materials: TiNSi, Ta, TaN, TaSiN, Ti, TiN, W, WN, WSiN, WCN, and Ru.

20. The structure of claim 13 wherein the first barrier layer is a flash PVD layer of Ta.

21. The structure of claim 13 wherein the flash barrier layer is a PVD layer of Ta and wherein depositing the second barrier layer is performed in the same PVD barrier chamber as the selective etching.
